(19) United States
(12) Patent Application Publication
(10) Pub. No.: US 2026/0028745 A1
(43) Pub. Date: Jan. 29, 2026

(54) CRUCIBLES WITH TRANSMISSION MODIFICATION AND METHODS FOR USING SUCH CRUCIBLES

(71) Applicant: GlobalWafers Co., Ltd., Hsinchu (TW)

(72) Inventor: Richard Joseph Phillips, St. Peters, MO (US)

(21) Appl. No.: 19/277,960

(22) Filed: Jul. 23, 2025

Related U.S. Application Data
(60) Provisional application No. 63/675,564, filed on Jul. 25, 2024.

(51) Int. Cl. C30B 15/10; C30B 29/06

(52) U.S. Cl. CPC C30B 15/10; C30B 29/06

(57) ABSTRACT

Crucibles for growing single crystal silicon ingots by the Czochralski method and methods for preparing a single crystal silicon ingot. The crucibles are characterized by transmission modification of the crucible body. A lower section of the crucible body may be made of silica doped with silicon. An upper section may be made of silica without quartz dopant.

### CROSS-REFERENCE TO RELATED APPLICATIONS

This application claims the benefit of U.S. Provisional Patent Application No. 63/675,564, filed Jul. 25, 2024, which is incorporated herein by reference in its entirety.

### TECHNICAL FIELD

The field of the disclosure relates to crucibles for growing single crystal silicon ingots by the Czochralski method and, in particular, crucibles with transmission modification of the crucible body.

### BACKGROUND

Oxygen control in Czochralski silicon is of high importance since the presence of oxygen in a silicon wafer affects the wafer strength, precipitation behavior, grown in point defectivity, and electrical properties. Crucibles used in Czochralski crystal growth are a source of oxygen in the silicon melt. Normally these crucibles have a wall construction where the inside layer is manufactured with a clear layer in which defects do not appreciably scatter light. Initially non-scattering or non-visible defects in the crucible wall can evolve in size, particularly on inside wetted surfaces, and can have a significant influence in the ability to grow zero dislocation single crystal silicon.

Conventionally, the non-wetted back half of the wall has a residual “bubble” composite, made of a mixture of bubbles and silica. This surface scatters light through the wall, and as the crucible is subjected to time at temperature, the bubbles in the composite grow larger, which can cause further scattering and less light transmission through the wall. Also, it is difficult to have a composite be transparent and remain transparent in a selected section of the crucible wall. Thus, process tuning requires power inputs to be adjusted which, from crucible to crucible, can cause additional variability in the crystal quality output. Further, many Czochralski process recipes attempt to axially bias heat or energy input so as to effect a desired flow cell(s) within the melt that in turn can regulate the interface shape as well as oxygen generation and uptake into the silicon crystal.

There exists a need to better control the transmission through the crucible wall as well as reducing the floating transmission variable with time at temperature as growth progresses in the Czochralski process.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a crucible for holding a silicon melt. The crucible includes a body. The body has a floor and a sidewall extending up from the floor. The floor and sidewall define a cavity for holding the silicon melt. The sidewall has a top, an inner surface, and an outer surface. The sidewall has a height that extends from the floor to the top of the sidewall. The body includes a first section and a second section. The first section comprises the floor. The first section comprises silica and elemental silicon dopant dispersed throughout the silica. The second section extends from the first section and towards the top of the sidewall. The second section comprises silica and is free of elemental silicon dopant.

Another aspect of the present disclosure is directed to a method for forming a single crystal silicon ingot. The method includes adding an initial charge of polycrystalline silicon to a crucible. The crucible includes a body having a floor and a sidewall extending up from the floor. The floor and sidewall define a cavity for holding the silicon melt. The sidewall has a top, an inner surface and an outer surface. The sidewall has a height that extends from the floor to the top of the sidewall. The body includes a first section and a second section. The first section includes the floor. The first section comprises silica and elemental silicon dopant dispersed throughout the silica. The second section extends from the first section and towards the top of the sidewall. The second section comprises silica and is free of elemental silicon dopant. The initial charge of polycrystalline silicon is heated to cause a silicon melt to form in the crucible. A silicon seed crystal is contacted with the silicon melt. The silicon seed crystal is withdrawn to grow a single crystal silicon ingot.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a cross-section view of an ingot puller apparatus before silicon ingot growth;

FIG. 2 is a cross-section view of the ingot puller apparatus of FIG. 1 during silicon ingot growth;

FIG. 3 is a perspective view of a crucible of the ingot puller apparatus of FIG. 1;

FIG. 4 is a cross-section view of the crucible and a susceptor;

FIG. 5 is a cross-section view of another embodiment of the crucible and the susceptor;

FIG. 6 is a reproduction of photographs of T-bars of clear-walled quartz and quartz doped with silicon as tested in Example 3;

FIG. 7 is a graph of transmissibility through silicon across various wavelengths; and

FIG. 8 is a graph of transmissibility through silica across various wavelengths.

Corresponding reference characters indicate corresponding parts throughout the drawings.

### DETAILED DESCRIPTION

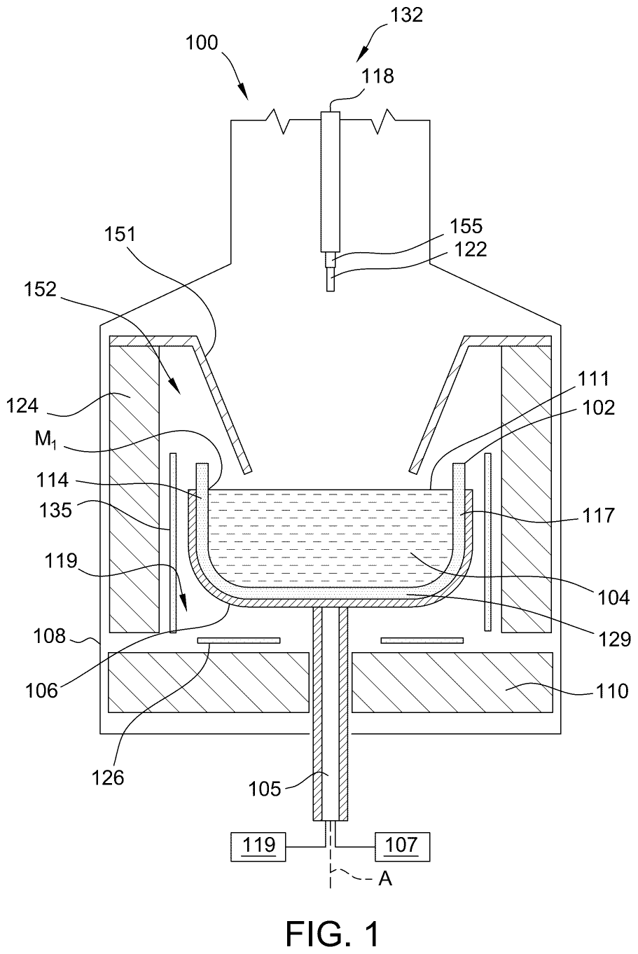

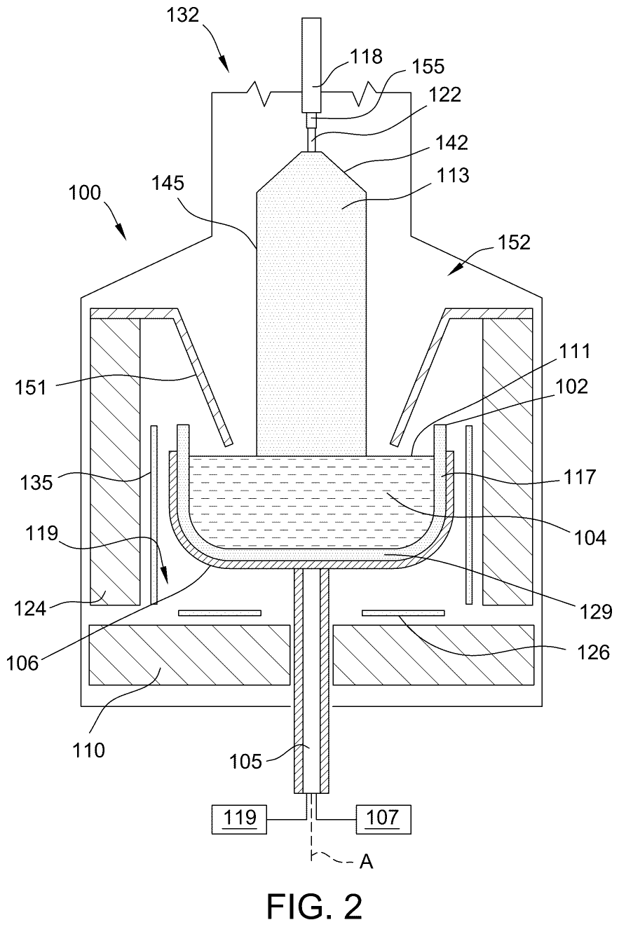

With reference to FIG. 1, provisions of the present disclosure relate to crucibles 102 for holding a silicon melt in an ingot puller apparatus 100. The ingot puller apparatus 100 and crucible 102 thereof are suitable for growing single crystal silicon ingots 113 (FIG. 2) by the Czochralski method.

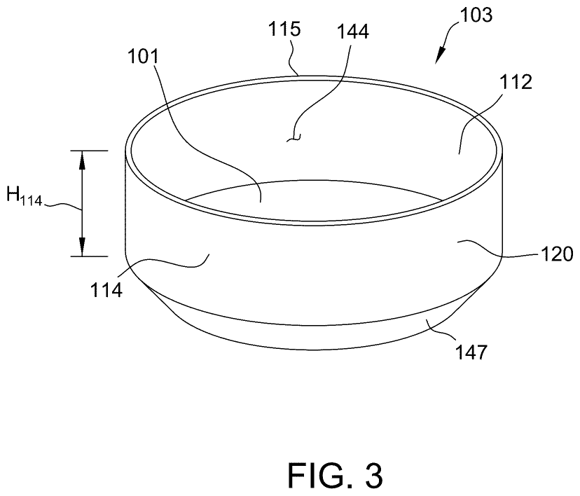

The crucible 102 includes a crucible body 103 (FIG. 3) made of quartz wherein at least a portion of the body is doped with silicon (i.e., elemental silicon). The crucible body 103 has a floor 101 and a sidewall 114 that extends from the floor 101. The floor 101 and sidewall 114 define a cavity 144 for holding the silicon melt.

The sidewall 114 is generally vertical and is cylindrical in shape. The sidewall 114 of the crucible body 103 has an inner surface 112 and an outer surface 120. The sidewall 114 has a top 115 and a height H₁₁₄ that extends from the floor 101 to the top 115. The floor 101 of the crucible body includes the curved portion 147 of the crucible body 103 that extends below the sidewall 131. The portion of the crucible body 103 adjacent the top 115 of the sidewall 114 may be referred to herein as the “rim” of the crucible.

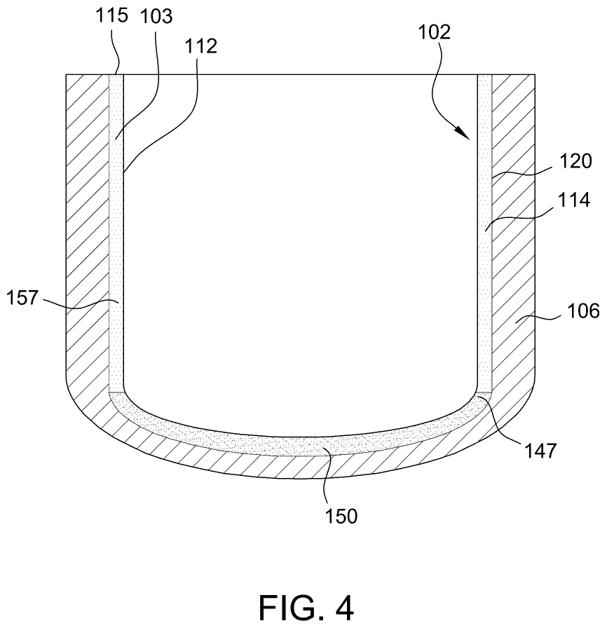

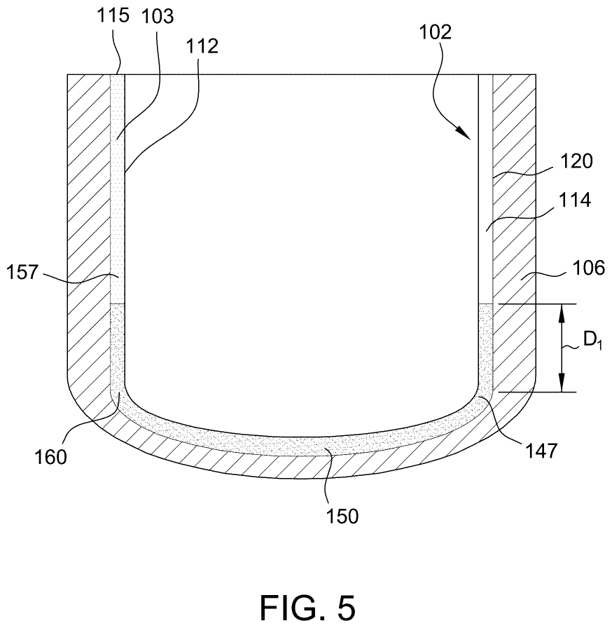

Referring now to FIG. 4, the crucible body 103 includes a first or “lower” section 150 and a second or “upper” section 157 disposed above the first section 150. The first section 150 includes the floor 101 (and in some embodiments and as shown in FIG. 5, a portion of the sidewall 114). The first section comprises silica (e.g., at least 75 wt %, at least 85 wt %, at least 95 wt %, at least 99 wt % silica or at least 99.9 wt % silica). The first section 150 also comprises elemental silicon that is dispersed through the silica. For example, the first section 150 may include a concentration of elemental silicon of at least 10 ppmw or, as in other embodiments, at least 50 ppmw, at least 100 ppmw, at least 500 ppmw, or at least 0.1 wt %, or at least 0.5 wt % (e.g., 10 ppmw to 1 wt %, or from 100 ppmw to 1 wt %).

The second section 157 is disposed above the first section 150. The second section 157 extends from the first section 150 towards the top 115 of the crucible body 103 (e.g., to the top 115 without a further section being disposed above the second section 157). The second section 157 comprises silica (e.g., at least 75 wt %, at least 85 wt %, at least 95 wt %, at least 99 wt % silica or at least 99.9 wt % silica) and is free of elemental silicon dopant (e.g., less than 1 ppmw or less than 0.5 ppmw).

In this regard it should be noted that, without departing from the scope of the present disclosure, the transition between sections may be graded or there may be an abrupt compositional change. In some embodiments, there is a transition section (not shown) disposed between the first section 150 and the second section 157 in which the crucible body 103 gradually transitions to being free of elemental silica as in the second section 157.

In some embodiments, the first section 150 includes a portion of the sidewall 114. For example, the first section 150 extends to a distance D₁ (FIG. 5) from the bottom 160 of the sidewall 114. In some embodiments, D₁ is no more than 50% of the height H₁₁₄ of the sidewall 114 (e.g., no more than 25%, or no more than 10% of the height H₁₁₄ of the sidewall 114).

In some embodiments, the crucible 102 does not include a coating or liner on the crucible body 103. In other embodiments, the crucible 102 include a coating or liner (e.g., synthetic quartz) disposed on the body 103. In some embodiments, a quartz base layer (e.g., clear-walled quartz) is coated (e.g., plasma sprayed) with silicon-doped silica.

The crucible body 103 may be formed by arc fusion. The silicon powder incorporated into the quartz may be a nanoparticulate to minimize time scales for inner diffusion and mixing of the silicon atoms into the silica. Other embodiments for producing a crucible with axially asymmetric transmissibility include slip cast methods and dry and sinter methods. Other embodiments include plasma spraying the silica doped with silicon composition on a base (e.g., clear-walled) material.

The crucibles 102 described above may be used to prepare a single crystal silicon ingot by the Czochralski process. The crucible may be generally used in any ingot puller apparatus that is configured to pull a single crystal silicon ingot. An example ingot puller apparatus (or more simply “ingot puller”) is indicated generally at “100” in FIG. 1. The ingot puller apparatus 100 includes the crucible 102 described above for holding a melt 104 of silicon. The crucible 102 is supported by a susceptor 106. The ingot puller apparatus 100 includes a crystal puller housing 108 that defines a growth chamber 152 for pulling a silicon ingot 113 (FIG. 2) from the melt 104 along a pull axis A.

The crucible 102 has a floor 129 and a sidewall 117 that extends from the base or floor 129. The sidewall 117 is generally vertical and is cylindrical in shape. The floor 129 of the crucible 102 includes the curved portion of the crucible 102 that extends below the sidewall 131. The crucible 102 is supported by a susceptor 106. The susceptor 106 is supported by a shaft 105. The susceptor 106, crucible 102, shaft 105 and ingot 113 (FIG. 2) have a common longitudinal axis A or “pull axis” A.

A pulling mechanism 132 is provided within the ingot puller apparatus 100 for growing and pulling an ingot 113 from the melt 104. Pulling mechanism 132 includes a pulling cable 118, a seed holder or chuck 155 coupled to one end of the pulling cable 118, and a silicon seed crystal 122 coupled to the seed holder or chuck 155 for initiating crystal growth. One end of the pulling cable 118 is connected to a pulley (not shown) or a drum (not shown), or any other suitable type of lifting mechanism, for example, a shaft, and the other end is connected to the chuck 155 that holds the seed crystal 122. In operation, the seed crystal 122 is lowered to contact the melt 104. The pulling mechanism 132 is operated to cause the seed crystal 122 to rise. This causes a single crystal ingot 113 (FIG. 2) to be withdrawn from the melt 104.

During heating and crystal pulling, a crucible drive unit 107 (e.g., a motor) rotates the crucible 102 and susceptor 106. A lift mechanism 132 raises and lowers the crucible 102 along the pull axis A during the growth process. For example, as shown in FIG. 1, the crucible 102 may be at a lowest position (near the bottom heater 126) in which an initial charge of solid-phase polycrystalline silicon previously added to the crucible 102 is melted. Crystal growth commences by contacting the melt 104 with the seed crystal 122 and lifting the seed crystal 122 by the pulling mechanism 132. As the ingot grows, the silicon melt 104 is consumed and the height of the melt in the crucible 102 decreases. The crucible 102 and susceptor 106 may be raised to maintain the melt surface 111 at or near the same position relative to the ingot puller apparatus 100 (FIG. 2).

A crystal drive unit (not shown) may also rotate the pulling cable 118 and ingot 113 (FIG. 2) in a direction opposite the direction in which the crucible drive unit 107 rotates the crucible 102 (e.g., counter-rotation). In embodiments using iso-rotation, the crystal drive unit may rotate the pulling cable 118 in the same direction in which crucible drive unit 107 rotates the crucible 102. In addition, the crystal drive unit raises and lowers the ingot 113 relative to the melt surface 111 as desired during the growth process.

The ingot puller apparatus 100 may include an inert gas system to introduce and withdraw an inert gas such as argon from the growth chamber 152. The ingot puller apparatus 100 may also include a dopant feed system (not shown) for introducing dopant into the melt 104.

According to the Czochralski single crystal growth process, a quantity of polycrystalline silicon, or polysilicon, is charged to the crucible 102. The initial semiconductor or solar-grade material that is introduced into the crucible is melted by heat provided from one or more heating elements to form a silicon melt in the crucible. The ingot puller apparatus 100 includes bottom insulation 110 and side insulation 124 to retain heat in the puller apparatus.

The ingot puller apparatus 100 includes a heating system 119 that is powered to transmit radiant heat to melt the initial charge and maintain the temperature of the melt 104 while withdrawing the silicon seed crystal to grow single crystal silicon ingot 113. In the illustrated embodiment, the ingot puller apparatus 100 includes a bottom heater 126 disposed below the crucible floor 129 and a side heater 135 disposed radially outward to the crucible sidewall 114. The crucible 102 may be moved to be in relatively close proximity to the bottom heater 126 to melt the polycrystalline charged to the crucible 102.

Before the ingot is grown, the melt 104 may be stabilized in a stabilization phase to cool the melt. To form the ingot after the stabilization phase, the seed crystal 122 is contacted with the surface 111 of the melt 104. The pulling mechanism 132 is operated to pull the seed crystal 122 from the melt 104. Referring now to FIG. 2, the ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone (not shown) in which the ingot tapers in diameter after the main body 145. When the diameter becomes small enough, the ingot 113 is then separated from the melt 104. Once the ingot 113 has been grown, the ingot is sliced into a plurality of silicon substrates (i.e., wafers).

The ingot puller apparatus 100 includes a side heater 135 and a susceptor 106 that encircles the crucible 102 to maintain the temperature of the melt 104 during crystal growth. The side heater 135 is disposed radially outward to the crucible sidewall 131 as the crucible 102 travels up and down the pull axis A. The side heater 135 and bottom heater 126 may be any type of heater that allows the side heater 135 and bottom heater 126 to operate as described herein. In some embodiments, the heaters 135, 126 are resistance heaters. The side heater 135 and bottom heater 126 may be controlled by a control system (not shown) so that the temperature of the melt 104 is controlled throughout the pulling process.

The ingot puller apparatus 100 may include a heat shield 151. The heat shield 151 may shroud the ingot 113 and may be disposed within the crucible 102 during crystal growth (FIG. 2).

The ingot growth process may be a batch process in which polycrystalline silicon is not added to the crucible 102 during ingot growth. In other embodiments, a continuous Czochralski process is used in which polycrystalline silicon is added to the crucible 102 during ingot growth (e.g., with the crucible having one or more fluid barriers that divide the crucible into various zones).

In accordance with embodiments of the present disclosure, the lower section 150 of the crucible body 103 blocks at least a portion of the radiant heat transmitted from the heating system 119. In some embodiments, the first section 150 is about 0% transmissible to the radiant heat transmitted from the heating system 119. In other embodiments, the first section 150 is less than 75%, less than 50%, less than 25% or less than 10% transmissible to the radiant heat transmitted from the heating system 119. The upper section 157 of the crucible body 103 may transmit at least 75%, at least 85%, or at least 95% of the radiant heat from the heating system 119.

Compared to conventional crucibles, the crucibles of the present disclosure have several advantages. The silicon dopant acts to alter the stoichiometry to achieve an oxygen deficient quartz as in SiO(2-x). This in turn changes the amount of total visible light being transmitted. Building a composite of silicon in silica may also alter the distribution of wavelengths transmitted through the crucible with more thermal energy being involved in the longer wavelengths (See Example 1).

Axial transmission asymmetry may be used to construct a crucible body with transmission adapted to yield a hotter melt. For example, a clear walled part (or nearly clear walled) in the upper straight wall can transmit heat into the upper melt region to heat the upper region. The lower bottom radius section(s) is doped to shunt the transmission, thus shielding the lower sections from heat sources such as bottom heaters or an oblique view from the lower section of the side heater. The lower transmission in the bottom keeps the melt below the crystal colder. Obtaining a colder melt region in the lower section below the crystal allows for a reduced amount of oxygen to be transported into the crystal, and thus a lower Oi level in the solidified crystal.

In addition to the potential to reduce oxygen in a single crystal silicon ingot in a Czochralksi process using transmission and engineering hot and cold flow cells, the basic erosion of a grey quartz body may further provide some accrued effect from the stoichiometry. The composite material itself could be manufactured over a wide range of compositions. A composite of silicon islands in silica matrix could be obtained. Yet with adequate diffusion time of the free silicon in SiO₂ after the initial consolidation, a non-islanded composite may be produced, where the stoichiometry becomes an oxygen deficient glass, such as SiO(2-x). In the stoichiometric sense for SiO₂, one molecule of SiO₂ dissolved into the silicon melt would yield 1 silicon atom with 2 oxygen atoms. However, in the case of SiO(2-x), for each Si atoms dissolved, (2-x) atoms of oxygen are dissolved instead of 2 oxygen atoms as in the stoichiometric case. Thus, for every molecule dissolved, a reduced amount of oxygen would be supplied into the melt.

### EXAMPLES

The processes of the present disclosure are further illustrated by the following Examples. These Examples should not be viewed in a limiting sense.

### Example 1: Transmission Comparison at Various Wavelengths for Silicon and Silica

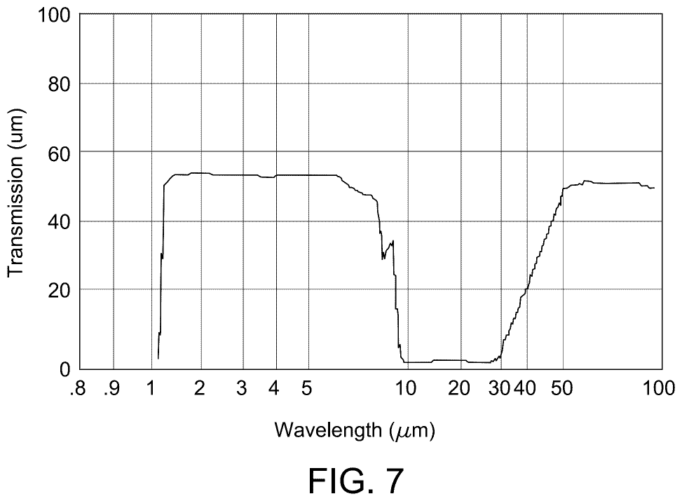

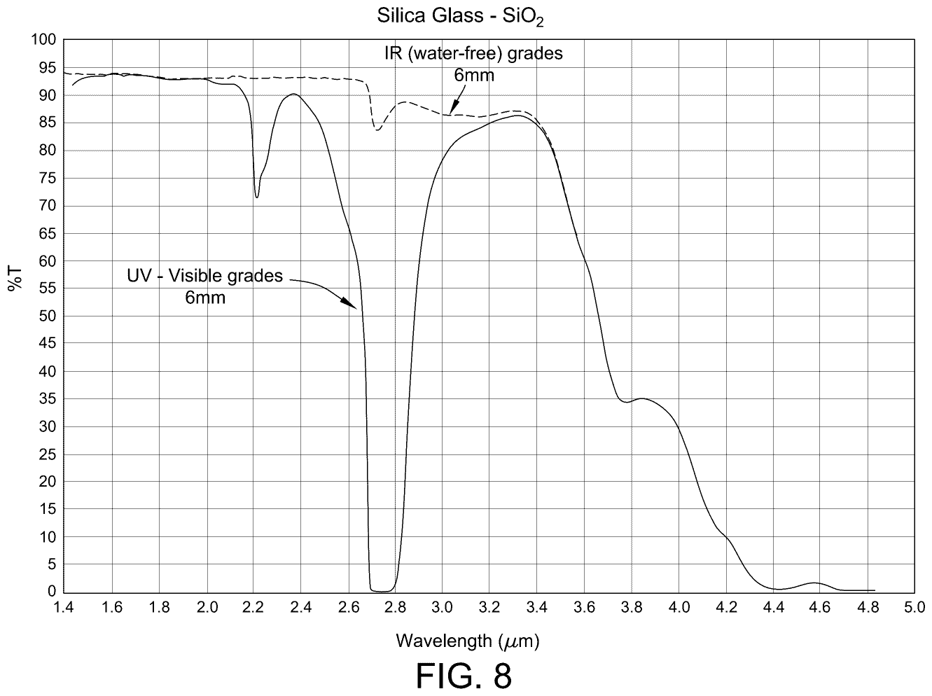

FIGS. 7 and 8 show the differences in the transmission curves for silica and silicon over a range of wavelengths. As shown in the Figures, silicon is able to increase non-transmissibility at a range of wavelengths in which silica is highly transmissible (e.g., 5 μm).

### Example 2: Production of Silica Doped with Silicon

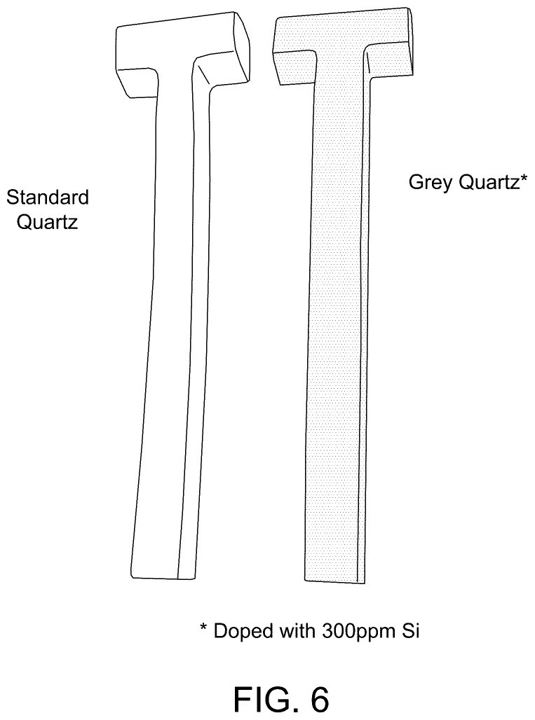

Silica doped with 300 ppmw silicon was used to obtain a black solid with essentially zero transmission. This material has been produced by a slip cast and sintering operation to yield a body devoid of large gas bubbles that would occur by the reaction between Si(s)+SiO₂(s) to yield 2 SiO(g) molecules. A sufficiently rapid consolidation process may be used to incorporate the silicon excess into the solid and avoid the SiO(g) formation. As shown in FIG. 6, the silica doped with silicon is black or grey quartz.

### Example 2: Erosion Comparison Between Clear-Walled Quartz and Silicon-Doped Quartz (Grey Body)

Initial results using side by side immersion tests of standard quartz verses grey quartz is shown in FIG. 6. The experimental conditions were 1575° C. at an ambient pressure of 10 torr under flowing argon. T-bars of grey and standard quartz were immersed for 5 hours in a small charge of silicon (250 grams). The melt line profiles were measured using profilometry at the melt line and the areas integrated. Using this method, the grey quartz showed approximately 5% less area dissolved compared to the standard quartz.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A crucible for holding a silicon melt, the crucible comprising:
a body having a floor and a sidewall extending up from the floor, the floor and sidewall defining a cavity for holding the silicon melt, the sidewall having a top, an inner surface and an outer surface, the sidewall having a height that extends from the floor to the top of the sidewall, the body comprising:
a first section that comprises the floor, the first section comprising silica and elemental silicon dopant dispersed throughout the silica; and
a second section that extends from the first section and towards the top of the sidewall, the second section comprising silica and being free of elemental silicon dopant.

2. The crucible as set forth in claim 1 wherein the first section comprises a portion of the sidewall.

3. The crucible as set forth in claim 2 wherein the first section extends to a distance D₁ from a bottom of the sidewall, wherein the distance D₁ is no more than 50% of the height of the sidewall.

4. The crucible as set forth in claim 1 wherein the concentration of elemental silicon dopant in the first section is at least 10 ppmw.

5. The crucible as set forth in claim 1 wherein the crucible does not include a coating on the crucible body.

6. The crucible as set forth in claim 1 wherein the floor of the crucible body includes a curved portion of the crucible body that extends below the sidewall.

7. A method for forming a single crystal silicon ingot comprising:
adding an initial charge of polycrystalline silicon to a crucible, the crucible comprising:
a body having a floor and a sidewall extending up from the floor, the floor and sidewall defining a cavity for holding the silicon melt, the sidewall having a top, an inner surface and an outer surface, the sidewall having a height that extends from the floor to the top of the sidewall, the body comprising:
a first section that comprises the floor, the first section comprising silica and elemental silicon dopant dispersed throughout the silica; and
a second section that extends from the first section and towards the top of the sidewall, the second section comprising silica and being free of elemental silicon dopant;
heating the initial charge of polycrystalline silicon to cause a silicon melt to form in the crucible;
contacting a silicon seed crystal with the silicon melt; and
withdrawing the silicon seed crystal to grow a single crystal silicon ingot.

8. The method as set forth in claim 7 comprising a heating system that transmits radiant heat, the heating system comprising a side heater and a bottom heater, the heating system being powered while withdrawing the silicon seed crystal to grow a single crystal silicon ingot, wherein the first section is about 0% transmissible to radiant heat transmitted from the heating system.

9. The method as set forth in claim 7 comprising a heating system that transmits radiant heat, the heating system comprising a side heater and a bottom heater, the heating system being powered while withdrawing the silicon seed crystal to grow a single crystal silicon ingot, wherein the first section is less than 50% transmissible to radiant heat transmitted from the heating system.

10. The method as set forth in claim 7 wherein the first section comprises a portion of the sidewall.

11. The method as set forth in claim 10 wherein the first section extends to a distance D₁ from a bottom of the sidewall, wherein the distance D₁ is less than the height of the sidewall.

12. The method as set forth in claim 7 wherein the concentration of elemental silicon dopant in the first section is at least 50 ppmw.

13. The method as set forth in claim 7 wherein the crucible does not include a coating on the crucible body.

14. The method as set forth in claim 7 wherein the crucible floor of the crucible includes a curved portion of the crucible that extends below the sidewall.

15. The method as set forth in claim 7 wherein the crucible is part of an ingot puller apparatus, the ingot puller apparatus comprising a heat shield that shrouds the ingot.
